(19) United States
(12) Patent Application Publication
(10) Pub. No.: US 2011/0084332 A1
(43) Pub. Date: Apr. 14, 2011

(54) TRENCH TERMINATION STRUCTURE

(75) Inventor: Lung-Ching Kao, Taipei (TW)

(73) Assignee: VISHAY GENERAL SEMICONDUCTOR, LLC., Columbus, NE (US)

(21) Appl. No.: 12/575,517

(22) Filed: Oct. 8, 2009

(51) Int. Cl. H01L 29/78; H01L 21/302; H01L 21/28

(52) U.S. Cl. 257/330; 438/689; 438/589; 438/700; 257/E29.255; 257/E21.214; 257/E21.158

(57) ABSTRACT

A trench MOS device includes a base semiconductor substrate, an epitaxial layer grown on the base semiconductor substrate, a first trench in the epitaxial layer, and a stepped trench comprising a second trench and a third trench in the epitaxial layer. There is a mesa between the first trench and the stepped trench. There is a spacer on a the sidewall of the second trench, wherein the third trench having a depth below the spacer. There is a dielectric layer extending along sidewalls and bottom walls of the second trench and the third trench. There is also a metal layer extending over the first trench, over a sidewall of the stepped trench and a portion of the bottom of the stepped trench.

### FIELD OF THE INVENTION

The present invention relates to a process for forming electrical components in a semiconductor substrate. More specifically, the present invention relates to forming an improved termination structure for trench-type power devices to decrease charge coupling and electromagnetic field crowding in order to reduce reverse-biased leakage current.

### BACKGROUND

MOS devices include such devices as Schottky diodes, IGBT, or DMOS depending on the semiconductor substrate prepared. U.S. Pat. No. 6,309,929, included in its entirety by reference, describes an earlier attempt to design trench MOS devices with a termination region that minimizes reverse-biased leakage current. That reference enables one to smooth the potential contour under reverse bias, but still demonstrates an approximately 8.2 percent leakage current. Computer simulations of that design revealed that the maximum electromagnetic field in the device was concentrated beneath the spacer of the trench termination structure. Charge coupling and field crowding were identified as the primary causes of this maximum electromagnetic field which caused the significant reverse-biased leakage current. Therefore, it was recognized that there was a need in the art for an improved termination structure for trench MOS devices that would further reduce charge coupling, electromagnetic field crowding and reverse-biased leakage current.

Therefore, a primary objective is to provide a trench MOS termination structure which further reduces electromagnetic field crowding.

Another objective is to provide a trench MOS termination structure which reduces charge coupling.

Another objective is to provide a trench MOS termination structure which reduces reverse-biased leakage current.

### SUMMARY

According to one aspect, a trench MOS device is provided. The device includes a base semiconductor substrate, an epitaxial layer grown on the base semiconductor substrate, a first trench in the epitaxial layer, and a stepped trench comprising a second trench and a third trench in the epitaxial layer. There is a mesa between the first trench and the stepped trench. There is a spacer on the sidewall of the second trench, wherein the third trench has a depth below the spacer. There is a dielectric layer extending along sidewalls and bottom walls of the second trench and the third trench. There is also a metal layer extending over the first trench, over a sidewall of the stepped trench and a portion of the bottom of the stepped trench.

According to another aspect, a trench MOS device and termination structure is provided. The device includes an N+ type base substrate layer, an N type epitaxial layer and a first trench in the epitaxial layer wherein the interior surfaces of the first trench are coated with an insulative layer and filled with a first conductive layer. There is also a stepped termination trench comprising a second and third trench wherein the first step is partially filled with a spacer comprising a first conductive material. There is also a dielectric layer covering at least a portion of the spacer, and the sidewalls and bottom surface of the third trench, and a second conductive layer covering the filled first trenches, a portion of the spacer, and a portion of the dielectric.

According to another aspect, a method for manufacturing a trench MOS device includes etching a third trench between spacers of a second trench, to form a stepped trench comprising the second trench and the third trench and to thereby provide a stepped trench MOS device.

According to another aspect, a method of simultaneously fabricating trench MOS devices and termination structure is provided. The method includes providing a semiconductor substrate having a first and second layer wherein the second layer is formed epitaxially on the first layer, the first layer being highly doped with a conductive impurity level and the second layer being doped to a lower conductive impurity level, coating the second layer in a hard mask layer, forming an oxide on the hard mask layer by chemical vapor deposition wherein the oxide is between 2,000 Å and 10,000 Å, etching a first trench and a second trench where the first trench is separated from the second trench by a mesa and wherein the second trench stretches from a boundary of the active region to an end of the semiconductor substrate, removing the oxide, growing a gate oxide layer with a thickness between 150 Å and 3,000 Å on the sidewalls and bottoms of the first trenches and the second trench through a high temperature oxidation process. The method further includes depositing a first conductive layer through CVD on the gate oxide which fills the first trench and the second trench to a level higher than the mesa. The method further includes anistrophically etching the portion of the first conductive layer above the mesa surface and from a center section of the second trench leaving spacers of the first conductive layer on a portion of the sidewalls and bottom of the second trench, etching a third trench between the spacers of the second trench, depositing a dielectric layer over a portion of a spacer and the sidewalls and bottom of the third trench, and depositing a second conductive layer through a sputtering process over at least a portion of the dielectric layer.

### BRIEF DESCRIPTION OF THE DRAWINGS

FIGS. 1 and 2 are cross sectional views of a prior art device; and

FIG. 3 is a cross sectional view of an embodiment of the present invention.

### DETAILED DESCRIPTION OF THE PREFERRED EMBODIMENTS

The present invention provides for an additional trench etch to reduce the charge coupling caused by electric field crowding and the strength of the electric field near the termination spacer. The embodiments disclosed below do not involve additional mask layers, but is able to reduce reverse-biased leakage current by as much as 30 percent more than alternative structures as shown in simulations. The termination region comprises a trench within a trench to form a stepped trench that stretches from the boundary of the active region to an end of the semiconductor substrate. This stepped trench structure is able to reduce charge coupling and electromagnetic field crowding and significantly reduce the resulting reverse-biased leakage current.

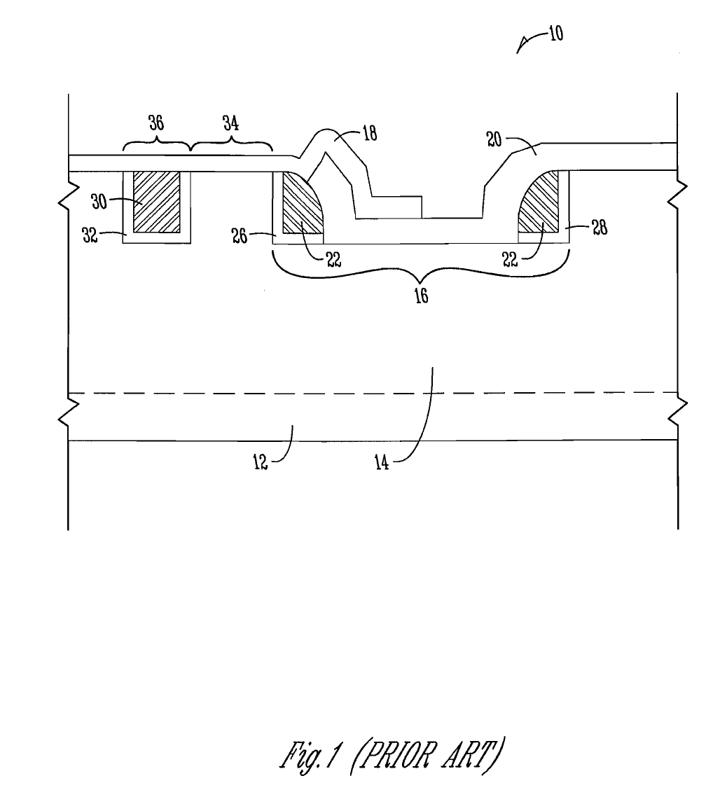

FIG. 1 provides a cross-section of a trench MOS device similar to that shown in U.S. Pat. No. 6,309,929. The trench MOS device 10 has a base semiconductor substrate 12 which is doped to a high conductive impurity level, for example n+. An epitaxial layer 14 is doped to a second conductive impurity level, for example, n, which is grown on the base semiconductor substrate 12. A first trench 36 is shown. In this example, the first trench 36 has an insulative layer 32 (e.g., gate oxide layer) and a conductive layer 30 (e.g., polysilicon, amorphous silicon . . . ). The first trench 36 is separated from a second trench 16 by a mesa 34. Spacers 22 are shown which are formed on the sidewalls 26, 28 of the second trench 16. A dielectric layer 20, such as a dielectric layer comprising TEOS, is shown which is at the bottom of the second trench 16 and extends upwardly over the sidewall 28 of the second trench 16. A metal layer 18 extends over the first trench 36, and extends over and beyond the sidewall 26 of the second trench 16.

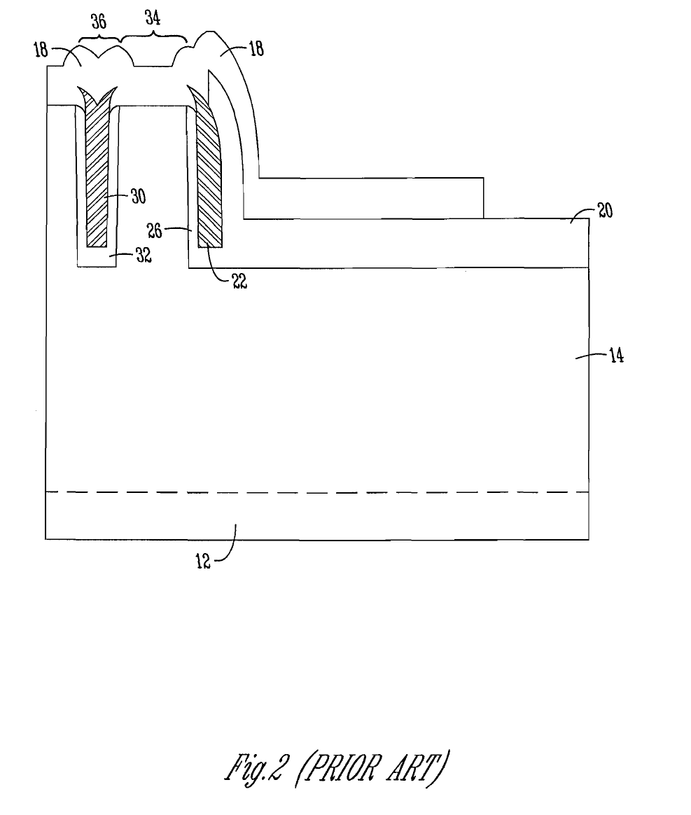

FIG. 2 illustrates the same prior art device as FIG. 1, with emphasis on the termination. The device shown in FIG. 1 and FIG. 2 will demonstrate certain leakage control issues. In operation, the device of FIG. 1 and FIG. 2 will develop a high electric field in the area beneath the spacer 22 located at the first sidewall 26 of the trench. In addition, the device of FIGS. 1 and 2 will develop a high electric field at the end of the metal layer 18 which terminates within the second trench 16.

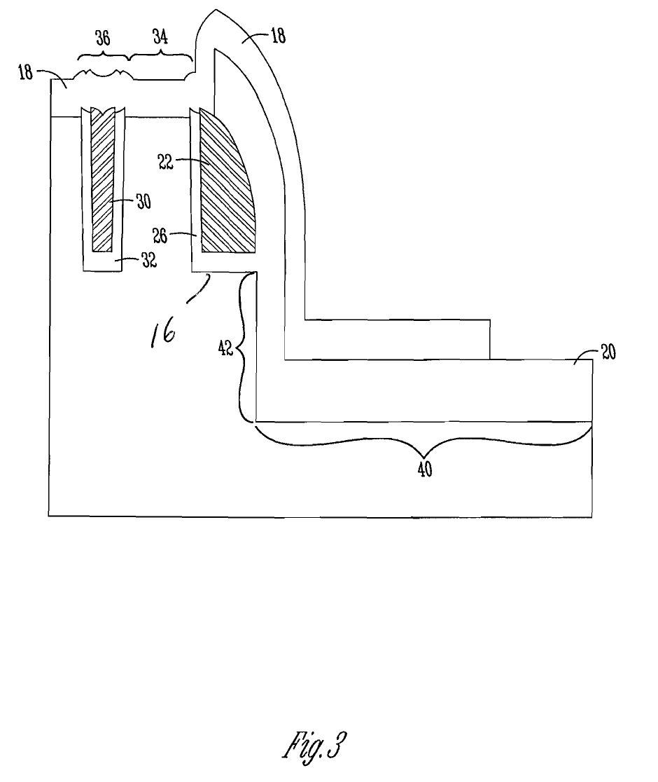

FIG. 3 illustrates the termination of the present embodiment. In FIG. 3, the geometric structure at the termination provides a stepped trench which is formed by the second trench 16 and a deeper trench 40. The deeper trench 40 has a depth 42 beyond the second trench 16. The bottom of the trench 40 extends beyond the depth of the first trench 36 and the spacer 22. The resulting structure has improved leakage control. In particular, in the embodiment of FIG. 3, high electric field occurs only near the side wall 26 of the spacer 22 and there is a relatively low electric field at both the bottom of the spacer 22 and the end of the metal layer 18. Due to impact ionization being positively proportional to electric field strength, less electric field crowding results in lower leakage. The present embodiment contemplates that the additional trench depth may vary based on process capability and the target for leakage control. For simulation purposes an additional 2 microns for the depth 42 was used.

Comparisons for simulation of the present embodiment to a design such as shown in FIG. 1 under the same conditions revealed significant improvements in leakage control. For example, with a TEOS layer of 0.6 microns, the prior art termination under reverse 100V under ambient temperature of 400 k had a leakage of 2.27E-8 A/um² (See Table 1: Test Case-Fox 0.6). Under the same conditions, the termination of the embodiment shown in FIG. 3 had a leakage level of only 1.57E-8 A/um² (See Table 1: Test Case-New Ter Fox 0.6), which is only 69 percent of the original unmodified trench termination. Thus, the present embodiment can reduce reverse-biased leakage current by as much as 30 percent over alternative structures.

Table 1 summarizes different simulation results for leakage for a design such as shown in FIG. 1 (Fox 0.x) and the embodiment shown in FIG. 3 (New Ter Fox 0.x) under different reverse voltages and with three different TEOS layer thicknesses (in this case, 0.4, 0.6 and 0.8 microns). Table 1 also includes simulation results for an “Active Cell” structure such as the type disclosed in U.S. Pat. No. 6,309,929.

TABLE 1

| | IR @ | IR @ | IR @ | IR @ | IR @ |
|---|---|---|---|---|---|
| | 10 V | 20 V | 50 V | 90 V | 100 V |
| Test Case | (A/um²) | (A/um²) | (A/um²) | (A/um²) | (A/um²) |
| Active Cell | 1.66E−09 | 2.25E−09 | 3.34E−09 | 5.00E−09 | 5.92E−09 |
| Fox 0.4 | 3.44E−09 | 6.77E−09 | 1.37E−08 | 2.21E−08 | 2.53E−08 |
| Fox 0.6 | 3.32E−09 | 6.19E−09 | 1.25E−08 | 1.99E−08 | 2.27E−08 |
| Fox 0.8 | 2.88E−09 | 5.45E−09 | 1.14E−08 | 1.85E−08 | 2.13E−08 |
| New Ter | 2.06E−09 | 3.20E−09 | 8.37E−09 | 1.46E−08 | 1.63E−08 |
| Fox 0.4 | | | | | |
| New Ter | 2.02E−09 | 3.10E−09 | 7.60E−09 | 1.38E−08 | 1.57E−08 |
| Fox 0.6 | | | | | |
| New Ter | 1.99E−09 | 3.05E−09 | 7.30E−09 | 1.35E−08 | 1.54E−08 |
| Fox 0.8 | | | | | |
| New Ter | 1.98E−09 | 3.02E−09 | 6.80E−09 | 1.31E−08 | 1.50E−08 |
| Fox 1.0 | | | | | |

Thus, the present embodiment provides for advantages in trench devices by providing an improved termination structure for trench MOS devices that would further reduce charge coupling, electromagnetic field crowding, and reverse-biased leakage current.

A method of manufacturing a trench device is also provided. According to the method of manufacturing the trench termination is etched without an additional mask. The self-aligned trench termination is provided with an additional trench etch to reduce the charge coupling caused by electric field crowding and the strength of the electric field near the termination spacer.

In order for the additional trench etch to form a new termination, an epitaxial layer (epi wafer) is capped with another hard mask layer (such as a nitride) before fabrication. Conventional trench etching processes are applied until the end of the second etch of the polysilicon. Because both mesa surfaces are still capped by nitride and the trench has been the sealed (such as by polysilicon), the only open area is the termination trench covered with a gate oxide at the bottom. Through etching selectively to dry etch both poly and nitride will become hard masks for removing oxide and silicon etching.

The present embodiment provides for numerous advantages. For example, no extra photo processes are needed when forming the additional trench. The termination provides for reduced electric field crowding at the termination bottom. The termination provides reduced leakage. In addition, the design allows a device application temperature to be higher.

A trench MOS device having an improved termination structure is fabricated by doping a base semiconductor substrate 12 to a high conductive impurity level, for example n+. An epitaxial layer 14 is doped to a second conductive impurity level, for example n, is grown on the base substrate 12. The epitaxial layer 14 is capped by a hard mask layer, such as a nitride. An oxide layer is formed on the hard mask layer by a chemical vapor deposition (CVD) process to about 2,000 Å to 10,000 Å.

A photoresist is coated on the oxide layer to define the first trench and a second trench. The first trench is about 0.2-2.0 um in width. The second trench is separated from the first trench by a mesa and reaches from the end of the boundary of the active region to an end of the semiconductor substrate. The oxide layer is removed, and then a high temperature oxidation process forms a gate oxide layer with a thickness between about 150 Å to 3,000 Å on the sidewalls, bottoms of the first trench and the second trench, and the surfaces of the mesa. Alternatively, the gate oxide layer can be formed by high temperature deposition to from a high temperature oxide (HTO) layer. Following the deposition of the gate oxide layer, a first conductive layer is formed by CVD on the gate oxide and fills the first trenches and the second trench to a height which is greater than the mesas. This first conductive layer also forms on the backside of the semiconductor substrate as an effect of the CVD process. The first conductive layer may be selected from the set comprising: metal, polysilicon, and amorphous silicon. The depth of the first conductive layer is preferably from 0.5-3.0 um.

An anistrophic etching is done to remove the excess first conductive layer above the mesa surface using the gate oxide layer on the mesa as an etching stop layer. A spacer approximately the width of depth of the second trench is formed on the sidewalls of the second trench. At this point the surface of the mesa is still capped by the hard mask layer, and the first trench and the sidewalls of the second trench are covered with the first conductive layer.

The portion of the second trench between the spacers covering the sidewalls is exposed. This portion is selectively etched by a dry etcher to create a third trench within the second trench between the spacers covering the sidewalls to create a stepped trench structure. A TEOS dielectric layer of LPTEOS, PETEOS, 03-TEOS, or an HTO layer is formed over a portion of a spacer, and the side walls and bottom of the third trench.

A photoresist pattern is coated on the dielectric layer to define the contacts. A dry etching exposes the mesa surface and the first conductive layer of the first trench. The photoresist pattern is stripped and the layers grown on the backside of the substrate (opposite the epitaxial layer) due to the thermal oxidation or CVD are removed. A sputtering process deposits a second conductive layer to form the contact regions and to form the cathode. Finally, a photoresist pattern is formed on the second conductive layer to define the anode. In a preferred embodiment the anode is formed from the active region extending to the second trench and at least 2.0 um away from the active region so that the bending region of the depletion region is far from the active region.

The present embodiment is an apparatus and method of fabrication for a trench termination structure for a trench MOS device that reduces reverse-biased leakage current and does not require additional mask layers.

Although specific disclosure is made throughout, the embodiments disclosed here in encompass numerous variations and alternatives. For example, variations in the materials used, the sizes, shapes, and geometries associated with the trench device, and other variations.

What is claimed is:

1. A trench MOS device comprising:
a base semiconductor substrate;
an epitaxial layer grown on the base semiconductor substrate;
a first trench in the epitaxial layer;
a stepped trench comprising a second trench and a third trench in the epitaxial layer;
a mesa between the first trench and the stepped trench;
a spacer on a the sidewall of the second trench, wherein the third trench having a depth below the spacer;
a dielectric layer extending along sidewalls and bottom walls of the second trench and the third trench; and
a metal layer extending over the first trench, over a sidewall of the stepped trench and a portion of the bottom of the stepped trench.

2. The trench MOS device of claim 1 wherein the third trench extends downward about 2 micrometers below the second trench.

3. The trench MOS device of claim 2 wherein the base semiconductor subtrate is an N+ type base substrate.

4. The trench MOS device of claim 3 wherein the epitaxial layer is an N type epitaxial layer.

5. A trench MOS device and termination structure comprising:
an N+ type base substrate layer;
an N type epitaxial layer;
a first trench in the epitaxial layer wherein the interior surfaces of the first trench being coated with an insulative layer and filled with a first conductive layer;
a stepped termination trench comprised of a second and third trench wherein the first step is partially filled with a spacer comprised of a first conductive material;
a dielectric layer covering at least a portion of the spacer, and the sidewalls and bottom surface of the third trench; and
a second conductive layer covering the filled first trenches, a portion of the spacer, and a portion of the dielectric layer.

6. The trench MOS device of claim 5 wherein the second trench extends downward to approximately a depth of the spacer and wherein the third trench extends downward substantially from the spacer to thereby reduce electric field beneath the spacer.

7. The trench MOS device of claim 5 wherein the third trench extends downward about 2 micrometers below the second trench.

8. The trench MOS device of claim 5 further comprising an anode layer covering at least a portion of the second conductive layer.

9. A method for manufacturing a trench MOS device comprising etching a third trench between spacers of a second trench, to form a stepped trench comprising the second trench and the third trench and to thereby provide a stepped trench MOS device.

10. A method of simultaneously fabricating trench MOS devices and termination structure comprising:
providing a semiconductor substrate having a first layer and a second layer wherein the second layer is formed epitaxially on the first layer, the first layer being high doped with a conductive impurity level and the second layer being doped to a lower conductive impurity level;
coating the second layer in a hard mask layer;
forming an oxide on the hard mask layer by chemical vapor deposition wherein the oxide is between 2,000 and 10,000 Å;
etching a first trench and a second trench where the first trench is separated from the second trench by a mesa and wherein the second trench stretches from a boundary of an active region to an end of the semiconductor substrate;
removing the oxide;
growing a gate oxide layer with a thickness between 150 A and 3,000 A on the sidewalls and bottoms of the first trenches and the second trench through a high temperature oxidation process;
depositing a first conductive layer through CVD on the gate oxide which fills the first trench and the second trench to a level higher than the mesa;
anistrophically etching the portion of the first conductive layer above the mesa surface and from a center section of the second trench leaving spacers of the first conductive layer on a portion of the sidewalls and bottom of the second trench;
etching a third trench between the spacers of the second trench;
depositing a dielectric layer over a portion of a spacer and the sidewalls and bottom of the third trench;
depositing a second conductive layer through a sputtering process over at least a portion of the dielectric layer.
